(19) United States
(12) Patent Application Publication
(10) Pub. No.: US 2026/0129930 A1
(43) Pub. Date: May 7, 2026

(54) SILICON CARBIDE TRANSISTOR WITH INTERRUPTED SOURCE CONTACTS

(71) Applicant: Navitas Semiconductor Limited, Dublin (IE)

(72) Inventors: Siddarth SUNDARESAN, Torrance, CA (US); Jaehoon PARK, La Crescenta, CA (US); Nathaniel WALSH, Redondo Beach, CA (US)

(73) Assignee: Navitas Semiconductor Limited, Dublin (IE)

(21) Appl. No.: 19/374,474

(22) Filed: Oct. 30, 2025

Related U.S. Application Data
(60) Provisional application No. 63/715,453, filed on Nov. 1, 2024.

(51) Int. Cl. H10D 62/10; H10D 30/01; H10D 30/66; H10D 62/832; H10D 64/23

(52) U.S. Cl. CPC H10D 62/124; H10D 30/0295; H10D 30/665; H10D 62/8325; H10D 64/2527

(57) ABSTRACT

A transistor includes a substrate having an active region having a first conductivity type. At least one stripe region is disposed in the active region, and each stripe region includes a well region, a source region, trenches, and a source conductor. The well region has a second conductivity type and a first depth, and the source region is disposed in the well region, has the first conductivity type, and has a second depth that is less than the first depth. The trenches are spaced apart and extend through the source region and into the well region, and each trench includes at least one sidewall. And the source conductor is disposed in each of the trenches and is electrically coupled to the source region at one or more sidewalls and to the well region.

### CROSS-REFERENCE TO OTHER APPLICATION

This application claims priority to U.S. provisional patent application Ser. No. 63/715,453, for “SILICON CARBIDE TRANSISTOR WITH UNINTERRUPTED SOURCE CONTACTS” filed on Nov. 1, 2024, which is hereby incorporated by reference in its entirety for all purposes.

### FIELD

The disclosed embodiments relate generally to transistor devices. More particularly, the disclosed embodiments relate to silicon-carbide-based transistor devices.

### SUMMARY

In the following description, various embodiments will be described. For purposes of explanation, specific configurations and details are set forth to provide a thorough understanding of the embodiments. However, it will also be apparent to one skilled in the art that the embodiments may be practiced without the specific details. Furthermore, well-known features may be omitted or simplified in order not to obscure the embodiment being described.

Certain embodiments of the present application relate to a silicon-carbide-(SiC)-based transistor device. The transistor device includes a plurality of transistor regions, arranged as “stripes” spaced apart by a pitch, which can be constant, and distributed across an active region of the SiC substrate. Each stripe includes a P-type doped region positioned adjacent a JFET region. An N-type doped “source” region is formed within each P-type doped region. A plurality of source-contact regions are formed within each N-type doped region and are separated by a contact spacing, which may be varied to achieve a desired ballast resistance for the transistor device. Each source-contact region is filled with an electrically conductive material (e.g., a source metal) that forms an electrical contact with the N-type doped region along the sidewalls of each source-contact region. Each source region also makes electrical contact with the P-type doped region along a bottom surface of the source-contact region.

Each P-type doped region includes a deep-implant region having a perimeter that is defined via a mask disposed on a top surface of the substrate such that changing the perimeter (e.g., width) of the P-type doped region does not change the pitch of the transistor. For example, a width of the deep-implant region can be increased without increasing the device pitch as the wide of the deep-implant region is not determined by a width of the P-type doped region or the N-type doped region. A top region of the transistor includes a source-metal layer that is electrically isolated from the underlying substrate by an interlayer dielectric, except where the source metal penetrates through the interlayer dielectric to fill the source-contact regions.

For example, a transistor device includes a substrate having top surface and an active region having a first conductivity type. At least one transistor region is disposed in the active region, and each of the at least one transistor region includes a well region, a source region, trenches, and a source electrode or conductor. The well region has a second conductivity type and a first depth from the top surface, and the source region is disposed in the well region, has the first conductivity type, and has, from the top surface, a second depth that is less than the first depth. The trenches are spaced apart (e.g., are “interrupted”) and extend from the top surface, through the source, and into the well region, and each trench includes at least one sidewall. And the source conductor is disposed in each of the trenches and is in conductive contact with, or otherwise is electrically coupled to, the source region and the well region at one or more of the at least one side walls.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

### BRIEF DESCRIPTION OF THE DRAWINGS

FIG. 1A is an isometric partial cross-sectional view of a transistor device, according to an embodiment.

FIGS. 1B-1E are partial cross-sectional views of a source-contact region of the transistor device of FIG. 1A during sequential manufacturing steps, according to an embodiment.

FIGS. 2A-2F are partial cross-sectional views of a source-contact region of a transistor device during sequential manufacturing steps, according to an embodiment.

FIG. 3 is a partial cross-sectional view of a transistor device during a manufacturing step, according to an embodiment.

FIG. 4 is a partial cross-sectional view of a transistor device during a manufacturing step, according to an embodiment.

### DETAILED DESCRIPTION

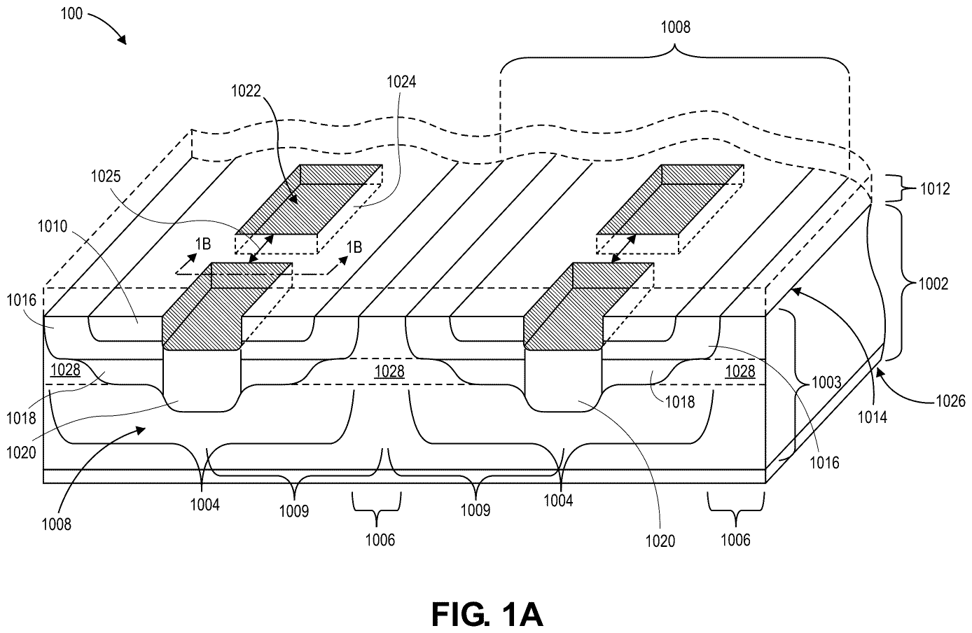

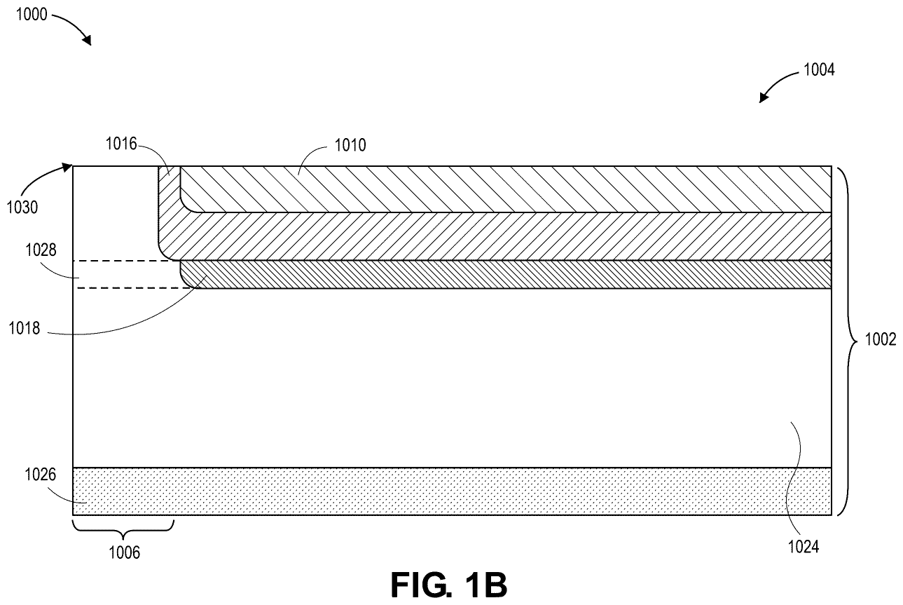

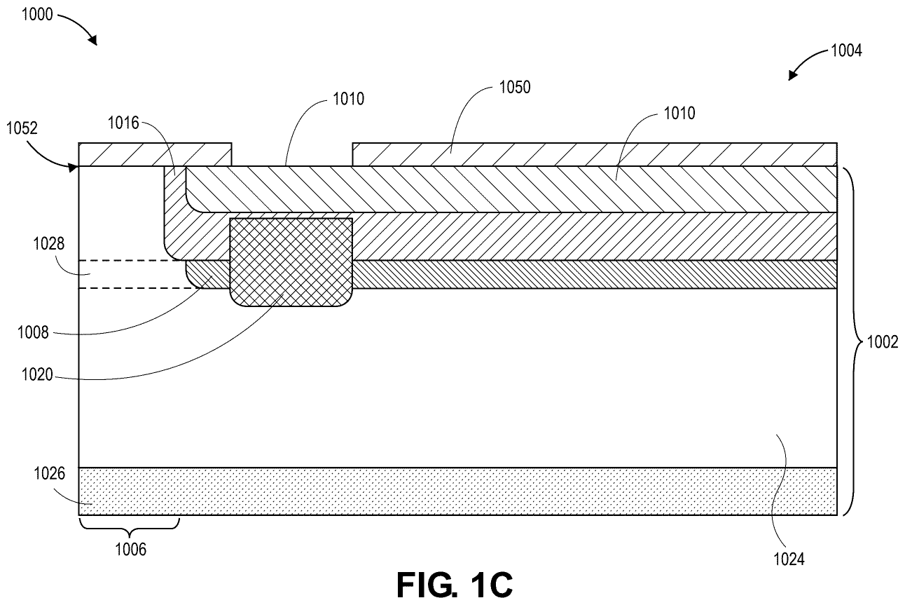

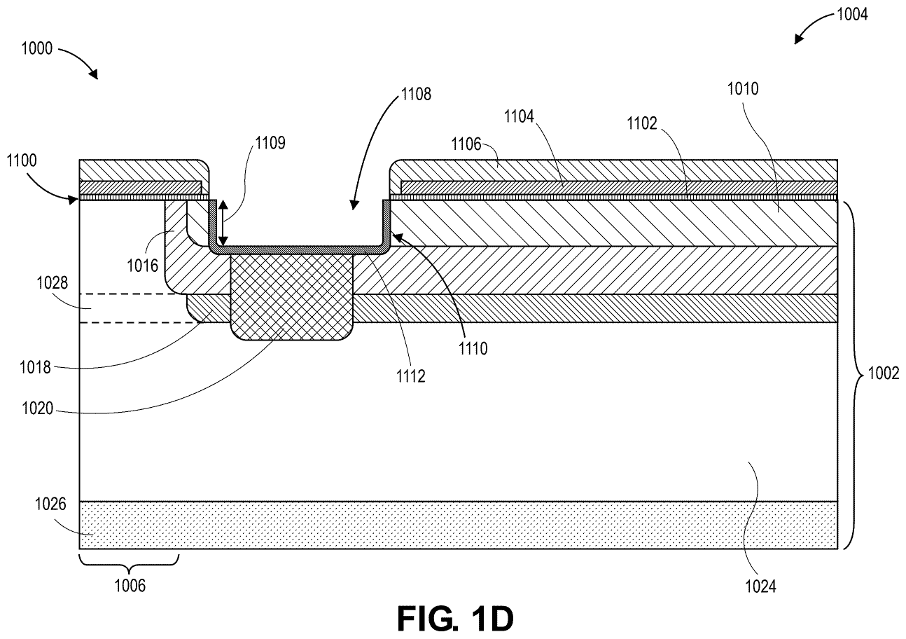

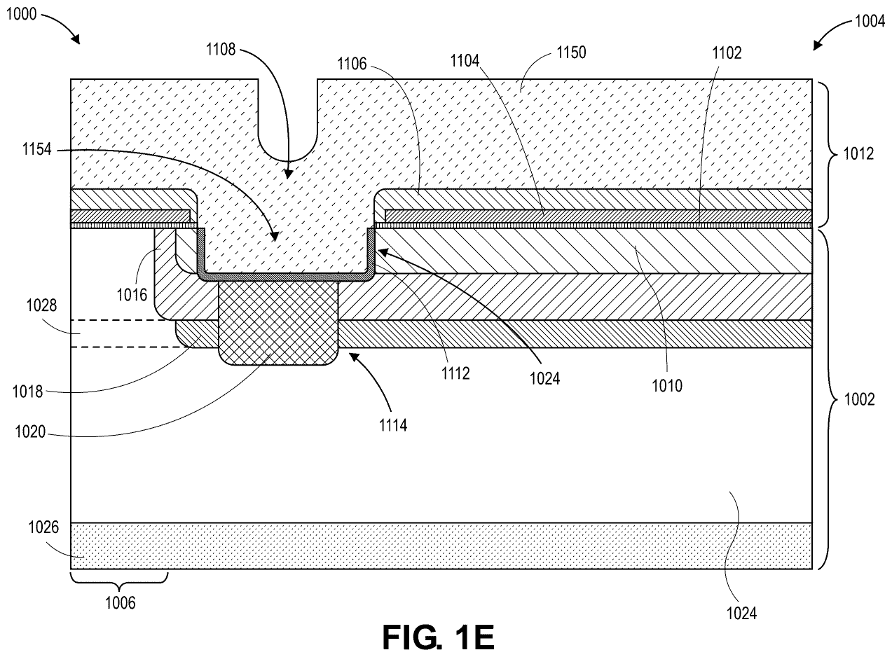

FIG. 1A depicts a simplified isometric partial cross-sectional view of a transistor device 1000, according to embodiments of the disclosure. As shown in FIG. 1A the transistor device 1000 includes a base semiconductor substrate 1002 that may be, or may include, silicon carbide (SiC), silicon (Si), gallium nitride (GaN), gallium arsenide (GaAs), or another suitable semiconductor material. The substrate 1002 includes an active region 1003 (sometimes called a “drift region”) having a first conductivity type (e.g., N⁻). A plurality of continuous doped regions (also called stripe regions) 1004 each having a second conductivity type (e.g., P) and continuous junction-field-effect-transistor (JFET) regions 1006 are distributed across the active region 1003 in a repeated “stripe” format with a constant stripe pitch 1008. Together, the doped/stripe regions 1004 and the JFET regions 1006 form respective transistor regions 1009 such that adjacent transistor regions share a JFET region 1006 and a doped/stripe region 1004. Continuous source regions 1010 having the first conductivity type (e.g., N⁺) are formed in a central portion of each doped/stripe region 1004, where a width of each source region 1010 is less than a maximum width of the doped/stripe region 1004. A top region 1012 of the transistor device 1000 is disposed across a top surface 1014 of the base substrate 1002 and includes a source metal layer (not delineated in FIG. 1A) that is electrically isolated from the base substrate 1002 via an interlayer dielectric (not delineated in FIG. 1A), as described in more detail below.

Unless otherwise noted, hereinafter the well regions 1016, second sinker regions 1018, and first sinker regions 1020 are described as P-doped or P-type regions, and the active region 1008 and the source regions 1010 are described as N-doped or N-type regions, it being understood that in other embodiments, one or more of the P-type regions may be N-type regions, and one or more of the N-type regions may be P-type regions.

Each doped/stripe region 1004 may include one or more subregions including a well region 1016 having the second conductivity type (e.g., P-type), a second sinker region 1018 having the second conductivity type (e.g., P-type), and a first sinker region 1020 having the second conductivity type (e.g., P-type) having different dopant levels and/or (dopant) depths in the substrate 1002 relative to the top surface 1014 of the substrate. In this particular embodiment, the well regions 1016 may include a first concentration of a P-type dopant and may be formed to a first depth in the substrate 1002, the second sinker regions 1018 may include a second concentration of a P-type dopant and may be formed to a second depth in the substrate, and the first sinker regions 1020 may include a third concentration of a P-type dopant and may be formed to a third depth in the substrate, where the third depth is greater than the second depth and the second depth is greater than the first depth, as described in more detail below. Alternatively, the doping of the well regions 1016 and second sinker regions 1018 may gradually shift, along a gradient, from a first dopant concentration at a top of the well regions toward a second dopant concentration at the bottom of the second sinker regions, such that portions of the well regions gradually become portions of the corresponding second sinker regions. Or, in an embodiment, each well region 1016 and each second sinker region 1018 can form a single, uniformly doped, region.

In some embodiments the P-type well regions 1016 and second sinker regions 1018 may be continuous stripes whereas the first sinker regions 1020 may be discontinuous and aligned with each source-contact region 1022, as described in more detail herein. In further embodiments, the first sinker regions 1020 may be continuous. In some embodiments, each of the second sinker regions 1018 may have similar doping profiles as each of the well regions 1016; that is, the doping profiles of the second sinker regions and well regions may be the same.

The N-type doped region 1010 is formed in the central portion of the P-type well region 1016 and functions as a “source” of the transistor device 1000. The N-type doped source region 1010 has a width that is less than the width of the P-type well region 1016. A plurality of source-contact regions 1022 are recessed into the top surface 1014 of the base substrate 1002 and are positioned within respective ones of the N-type doped source regions 1010. The source-contact regions 1022 are filled with a source metal (and/or electrically conductive interlayer, e.g., silicide on the source-contact-region side walls), which is part of the top region 1012, such that electrical connections can be made between the source-metal layer and the N-type doped source regions 1010. More specifically, each source-contact region 1022 is filled with source metal and potentially one or more other metals (e.g., a silicide) that forms/form an electrical contact with the corresponding N-type doped source region 1010 along sidewalls 1024 of each source-contact region 1022 (the sidewalls can include a bottom of a source-contact region as well as the four walls of the source-contact region). Although the source-contact regions 1022 are illustrated as rectangular shapes, they may have any other suitable geometry or shape including, but not limited to, oval, elongated oval, hexagonal, circular, or undulating/serpentine, which geometry may increase or decrease the area of the sidewalls 1024 of each source-contact region. In some embodiments, a value of a conventional ballast resistance or resistor (not shown in FIG. 1A) of the transistor device 1000 can be changed by varying the spacing 1025 between each adjacent pair of source-contact regions 1022. The spacing 1025 may be uniform between each adjacent pair of source-contact regions 1022, or may be non-uniform, i.e., different from one adjacent pair of source-contact regions to another adjacent pair. When the spacing 1025 is non-zero, the source-contact regions may be called “interrupted” source-contact regions (or “interrupted” source trenches, see below) 1022.

The P-type-doped first-sinker regions 1020 can be formed using a deep-implant process that is performed through a mask (not shown in FIG. 1A) disposed across the top surface 1014 of the substrate 1002. The implant energy defines the depth of the implant and the mask defines the perimeters of the deep implant such that changing the perimeters (e.g., widths) of the P-type first sinker regions 1020 does not change the strip pitch 1008 of the transistor 1000. For example, because the first sinker regions 1020 are formed via a deep implant and have perimeters that are independent of the dimensions, doping profile, or doping concentration of the corresponding N-type source regions 1010, a perimeter (e.g., width) of a P-type first sinker region 1020 can be increased without requiring a commensurate increase in the corresponding N-type source region 1010, which commensurate increase could cause an increase in the stripe pitch 1008. In other embodiments, each P-type-doped first sinker region 1020 may be formed in a continuous “stripe” and may not be defined as “interrupted” first-sinker regions aligned with each “interrupted” source-contact region 1022. An example manufacturing process for the transistor device 1000 described in FIG. 1A is described in more detail below.

The JFET regions 1006 can act as drain regions of the corresponding transistor regions 1009, and a positive voltage equal to or greater than a transistor threshold voltage applied to a gate (not shown in FIG. 1A) of the transistor 1000 forms channel regions in the portions of the well regions 1016 adjacent to the top surface 1014 of the substrate 1002 such that current flows from a bottom 1026 of the substrate 1002, through the active region 1008 and into the JFET regions 1006, across the formed channel regions, into the sources 1010 and conductive source contact regions 1022, and out of the source contact regions through a source electrode (not shown in FIG. 1A). Although not shown in FIG. 1A, there may be a drain electrode disposed over the bottom 1026 of the substrate 1002. Furthermore, optional current-spreading layer (CSL) regions 1028 disposed laterally between the second sinker regions 1018 reduce current densities in the JFET regions 1006 to reduce current-induced temperatures in the JFET regions and, therefore, can reduce the odds of, or prevent, overheating of the transistor 1000 while the transistor is “on.” For example, the CSL regions 1028 can be, or can be formed from, a material including indium-tin-oxide (ITO), graphene, carbon nanotubes, or gallium phosphide (GaP).

### Example Manufacturing Process

FIGS. 1B-1E depict simplified partial cross-sectional views of portions of a doped/stripe region 1004 and a JFET region 1006, including a source-contact region 1022, of the transistor device 1000 along a plane defined by line 1B-1B of FIG. 1A during sequential self-aligned manufacturing steps, according to an embodiment. Although formation and structure of only a portion of the transistor 1000 is depicted in FIGS. 1B-1E, it is understood that the remaining portions of the transistor can be formed or structured in a similar manner.

FIG. 1B depicts an intermediate structure of the transistor 1000 during a first manufacturing step according to an embodiment in which the base substrate 1002 can include an N-type (e.g., N⁻) drift layer 1024 disposed on an N-type (e.g., N⁺) substrate layer 1026. In some embodiments, the N-type drift layer 1024 can be grown epitaxially from the substrate layer 1026, or otherwise can be formed using an epitaxial wafer, and can have a suitable doping concentration (e.g., 10¹⁴-10¹⁸ cm⁻³) of an N-type dopant (e.g., phosphorous) and a suitable thickness (e. g., 1 μm-300 μm).

In some embodiments the well region 1016 can be formed in the drift layer 1024 of the substrate 1002 by depositing and patterning a first hard mask (not shown in FIG. 1B) on a top surface 1030 of the drift layer 1024 and then by performing a dopant (e.g., a P-type-dopant) implantation or epitaxial-growth step. If the implantation step is of a P-type dopant, then the implantation step can be performed using, for example, boron or aluminum.

Before the first hard mask (not shown in FIG. 1B) is removed, a second hard mask (not shown in FIG. 1B) can be deposited and patterned. The second hard mask can be deposited by, for example, a chemical vapor deposition (CVD) of a layer of silicon oxide, silicon nitride, silicon oxynitride, or of a metal such as nickel on top of the patterned first hard mask (not shown in FIG. 1B).

The source region 1010 can be formed in a region defined by the second hard mask (not shown in FIG. 1B) via implantation or epitaxial regrowth using dopant impurities such as, for example, nitrogen or phosphorous if the implantation or regrowth is N-type. The source region 1010 can be formed in a self-aligned fashion with the well region 1016, for example, as described in U.S. Pat. No. 11,075,277, which is herein incorporated by reference in its entirety for all purposes. The source region 1010 can have a smaller (as shown in FIG. 1B), larger, or similar footprint as the well region 1016.

In some embodiments, the second-sinker region 1018 may be formed at a same time as, and using the same mask as used for forming, the source region 1010. The second-sinker region 1018 may be formed, for example, by implanting a dopant (such as aluminum or boron if the second sinker region is to be P-type) below the source region 1010 at a greater depth in the drift region 1024 than the depth of the well region 1016. If the substrate 1002 is a silicon-carbide (SiC) substrate and the second-sinker region 1018 is to be P-type, then the second sinker region may be formed by implanting a P-type dopant, for example boron, which can have, for a given ion-implantation energy, a higher ion-implantation range in SiC as compared to other P-type dopants such as aluminum.

After formation of the source region 1010, the well region 1016, and the second sinker region 1018, the first and second hard masks (not shown in FIG. 1B) can be removed in a conventional manner.

FIG. 1C illustrates a second manufacturing step during which a third mask 1050 can be deposited on a top surface 1052 of the substrate 1002 and patterned, according to an embodiment. The third mask 1050 can be formed, for example, by CVD depositing a layer of silicon oxide, silicon nitride, silicon oxynitride, or of a metal such as nickel. The first-sinker region 1020 can be formed by a deep implant of a controlled dose of an impurity, such as, for example, aluminum or boron if the first-sinker region is to be P-type. The first sinker region 1020 can be disposed below a corresponding source region 1010 and can be electrically connected to (e.g., formed at least partially within) the well region 1016 and the second sinker region 1018 (where, for example, the second sinker region extends up to the source region as shown in FIG. 1A). The first-sinker region 1020 may have a greater maximum depth in the drift layer 1024 than both the well region 1016 and the second sinker region 1018.

After formation of the first-sinker region 1020, the third mask 1050 can be removed, and, if the substrate 1002 is an SiC substrate, then the implanted layers or regions can be activated through a high-temperature anneal that can be conventional for SiC transistors (e.g., SiC power transistors or SiC power devices) such as the transistor 1000, which would be an SiC transistor if formed in an SiC substrate. If the substrate 1002 is not an SiC substrate, then the implanted layers or regions can be activated in a conventional manner that corresponds to the type of the substrate 1002.

FIG. 1D illustrates a third manufacturing step in which an insulator layer, e.g., an oxide layer, can be formed over a top 1100 of the base substrate 1002 (or drift layer 1024) by, for example, a thermal oxidation or CVD process. The insulator layer can be a dielectric material, such as, for example, silicon dioxide, silicon nitride, or silicon oxynitride. The insulator layer can have a thickness, for example, between 10 nm and 100 nm. If the insulator layer is an oxide (e.g., silicon dioxide) layer, one can form the insulator layer using either dry or wet thermal oxidation. The gate insulator layer can be deposited using, for example, plasma-enhanced chemical-vapor deposition (PECVD) or low-pressure chemical-vapor deposition (LPCVD).

A conductive gate layer, e.g., a polysilicon gate layer, may be deposited over the gate insulator layer using, for example, PECVD or LPCVD. The conductive gate layer may be degenerately doped using, for example, boron or phosphorus, either in-situ or in a subsequent step. In-situ doping may be performed by an addition of a phosphine (PH3) precursor to a polysilicon deposition chemistry. Post-deposition doping of polysilicon may be performed by depositing a layer of phosphoryl chloride (POCL₃) followed by a drive-in step.

A fourth mask (not shown in FIG. 1D) can be deposited and patterned on a top surface of the conductive gate layer, which, as described above, is formed over the insulator layer. A gate insulator 1102 and a conductive gate 1104 can be formed, for example can be etched, from the gate insulator layer and conductive gate layer, respectively, using the patterned fourth mask.

The fourth mask can be removed after the formation of the gate insulator 1102 and the gate 1104.

An interlayer dielectric (ILD) layer then can be formed, e.g., deposited, over the gate 1104. The ILD layer can include, for example, 50 nm-1000 nm thick silicon dioxide, silicon nitride, one or more silicon oxynitride layers, or a combination of insulator layers.

A fifth mask (not shown in FIG. 1D) then can be formed, e.g., deposited, over the ILD layer and patterned. An ILD 1106 then can be formed from the ILD layer using the fifth mask. One or both of the gate insulator 1102 and the gate 1104 also can be etched and patterned (or further etched and patterned) using the patterned fifth mask. The fifth mask also can be used to define the source-contact regions 1022, which, in FIG. 1D, are shown as recessed regions, or source trenches 1108, by etching completely through the source regions 1010 (only one source region shown in FIG. 1D) into the corresponding well regions 1016 and into the corresponding first-sinker regions 1020.

After formation of the ILD 1106, and optionally after the formation of the gate 1104, the gate insulator 1102, and the recessed regions (e.g., source trenches or trenches) 1108, the fifth mask can be removed.

In an embodiment, a depth 1109 of each source trench 1108 is greater than a depth of each corresponding source region 1010.

Next, one or more ohmic-contact materials, such as, for example, nickel-silicide, can be formed on an exposed surface of the SiC wafer including sidewalls 1110 (“sidewalls” also can include the trench bottom) of the trench 1108 (e.g., the source-contact region 1022 of FIG. 1A) to form an ohmic contact 1112. That is, in an embodiment depicted in FIG. 1D, the ohmic contact 1112 to the source region 1010 can be made through and over or on one or more of the etched sidewalls 1110 of the trench 1108. But in other embodiments, the ohmic contact 1112 alternatively may be made through a top surface of the source region 1010 remote from the trench 1108. Furthermore, in an embodiment depicted in FIG. 1D, the ohmic contact 1112 also can contact, electrically, the well 1016, the second sinker region 1018, and/or the first sinker region 1020.

FIG. 1E illustrates a fourth manufacturing step in which a source metal layer (e.g., aluminum) then can be formed (e.g., deposited) over the transistor device 1000 at the indicated stage of manufacture to form a source electrode or terminal 1150. The source metal layer may be deposited within each recess/trench region 1108 (thus forming source contacts 1154 together with the ohmic contact 1112) and may be coupled electrically to the sidewalls 1024 of each contact well (e.g., trench 1108) via the ohmic contact 1112 and to a portion of the doped (e.g., P-type) region 1114 (e.g., the well 1016, the first sinker region 1020, and/or the second sinker region 1018).

The optional CSL 1028 can be formed during any of the one or more above-described manufacturing steps in a conventional manner or can be formed before or after the above-described manufacturing steps in a conventional manner.

Further details regarding a self-aligned manufacturing process that can be used to manufacture the transistor device 1000 can be found in U.S. Pat. No. 11,075,277, which is herein incorporated by reference in its entirety for all purposes.

### Dual-Metal Ohmic Contact

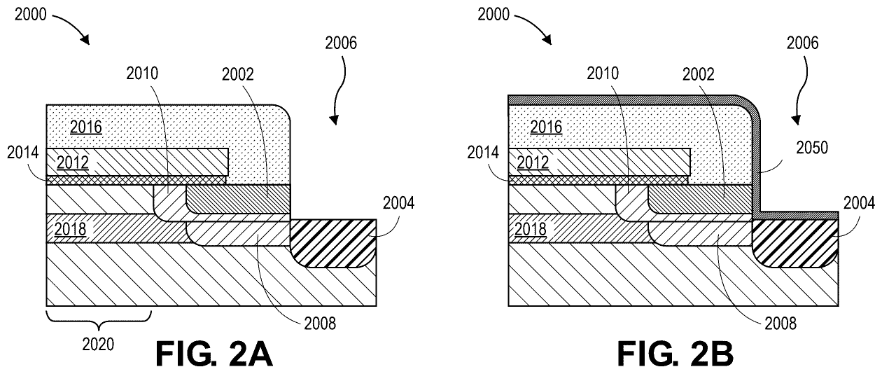

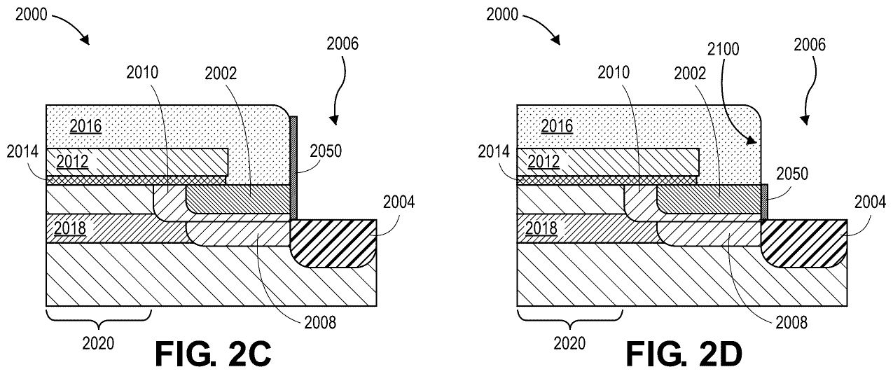

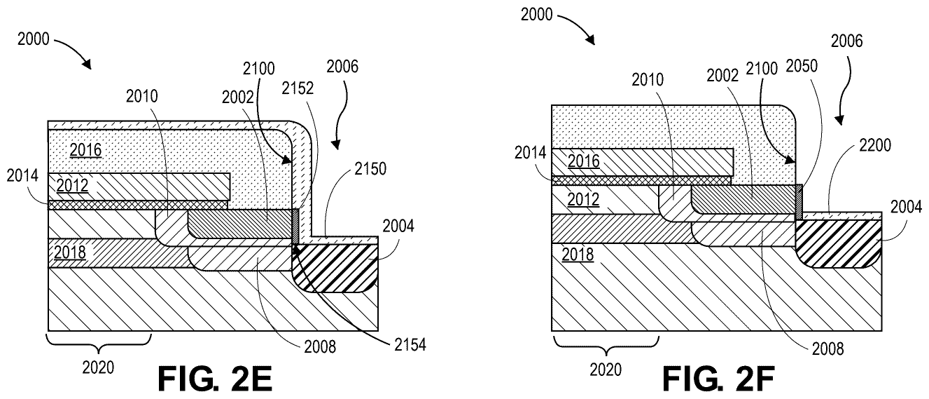

FIGS. 2A-2F depict simplified partial cross-sectional views of a transistor device 2000 during sequential steps for manufacturing the transistor device, according to embodiments of the disclosure.

As shown in FIG. 2A, the transistor device 2000 may be similar to the transistor device 1000, the structure and manufacture of which are described in conjunction with FIGS. 1A-1E; however, the transistor device 2000 includes an ohmic contact layer (not shown in FIG. 2A) made from at least two different conductive materials, e.g., metals. More specifically, a first metal (not shown in FIG. 2A) can be formulated to form a low-contact resistance with a source region (e.g., doped N⁺) 2002 and a second metal can be formulated to form a low-contact resistance with a first sinker (e.g., doped P⁻, P, or P⁺) region 2004 such that the transistor device 2000 may have a lower contact resistance with the source 2002 and first sinker regions 2004 than the transistor device 1000. The transistor device 2000 may be, or may include, any of the components, features, or characteristics of any of the transistor devices (e.g., the transistor device 1000) previously or subsequently described. And the features of the transistor device 2000 may be included in any of the transistor devices (e.g., the transistor device 1000) as previously or subsequently described. Furthermore, although FIGS. 2A-2F depict manufacture and intermediate structures of only a portion of the transistor device 2000, it is understood that the remaining portions of the transistor device can be formed and structured in a similar manner.

FIG. 2A depicts a simplified partial cross-sectional view of transistor device 2000 after a source contact region, e.g, trench 2006 has been etched through the source region (e.g., doped N⁺) 2002, through a portion of a second sinker (e.g., doped P⁻, P, or P⁺) region 2008, and into the first sinker (e.g., doped P⁻, P, or P⁺) region 2004. The transistor device 2000 also includes a well (e.g., P-type) region 2010, a conductive gate (e.g., a polysilicon gate) 2012, a gate insulator (e.g., a gate oxide) 2014, an ILD 2016, a CSL 2018, and a JFET region 2020.

FIG. 2B depicts a simplified partial cross-sectional view of the transistor device 2000 after a first metal layer 2050 has been formed (e.g., deposited) across (e.g., over, on) the interlayer dielectric (ILD) 2016, the source region 2002, a portion of the second sinker region 2008, and across (e.g., over, on) a top of the first sinker region 2004. In some embodiments, the first metal layer 2050 can be formulated to form a low-contact-resistance connection to the source region 2002. In one example, the first metal layer 2050 is nickel or includes nickel as one component. After formation (e.g., deposition) of the first metal layer 2050, the transistor device 2000 can be annealed at a first annealing temperature that is designed to react the first metal layer with the source region 2002, for example, to form nickel silicide.

FIG. 2C depicts a simplified partial cross-sectional view of the transistor device 2000 of FIGS. 2A-2B after a blanket etching process (e.g., a dry etch or other type of reactive-ion etch (RIE) or anisotropic etch) that has removed portions of the first metal layer 2050 from predominantly horizontal surfaces of the intermediate structure of the transistor device 2000. In some embodiments, the first annealing step described in FIG. 2B may be performed after the blanket etching process.

FIG. 2D depicts a simplified partial cross-sectional view of the transistor device 2000 after a second metal-layer removal (e.g., wet or dry etching process) that has removed a portion of the first metal layer 2050 from vertical surfaces (e.g., from a sidewall 2100 of the ILD layer 2016). In some embodiments, the removal (e.g., etch) can be formulated to remove only the portions of the first metal layer 2050 that have not reacted with the source region 2002 (e.g., to form nickel-silicide) such that the remaining portions of the first metal layer are effectively self-aligned to exposed portions of the source region 2002 and/or the second sinker region 2008.

FIG. 2E depicts a simplified partial cross-sectional view of the transistor device 2000 after a second metal layer 2150 has been deposited over the ILD 2016, the remainder 2152 of first metal layer 2050, the first sinker region 2004, and optionally over an exposed portion (not shown in FIG. 2E) of the second sinker region 2008. In some embodiments, the second metal layer 2150 can be formulated to form a low-contact-resistance connection to the first sinker region 2004 and optionally with the second sinker region 2008. In an example, the second metal layer 2150 includes titanium and/or aluminum. After formation (e.g., deposition) of the second metal layer 2150, the transistor device 2000 can be annealed at a second annealing temperature that is designed to cause the second metal layer to react with the first sinker region 2004. In further embodiments, the second metal layer 2150 may include nickel, and may be annealed at a lower annealing temperature than the first annealing temperature described above with regard to the intermediate structure of the transistor 2000 of FIG. 2B, where the lower annealing temperature is designed to improve, or to optimize, a low-contact resistance between the remaining portion of the first metal layer 2050 (e.g., between the remaining portion of the first metal layer including nickel) and the first sinker region 2004 along a region 2154 where the remaining portion of the first metal layer and the first sinker region are contiguous.

FIG. 2F depicts a simplified partial cross-sectional view of the transistor device 2000 after most of the second metal layer 2150 has been removed via one or more wet or dry etching processes. In some embodiments, the etching processes can be designed to remove only portions of the second metal layer 2150 that have not reacted with the first sinker region 2004 or optionally with the second sinker region 2008. Thus, the remaining portion 2200 of the second metal layer 2150 effectively can be self-aligned to the first sinker region 2004 and optionally to the second sinker region 2008 (this optional effective self-alignment is not shown in FIG. 2F). The transistor device 2000 can continue to be fabricated, for example, by using the remaining steps described above with regard to FIGS. 1A-1E, or by using another suitable process or another one or more suitable process steps. In an embodiment, a relatively thick source metal (e.g., aluminum, not shown in FIG. 2F) is formed (e.g., is deposited) and forms an electrical connection with both the remaining portions of the first metal layer 2050 and the second metal layer 2150 such that a low-contract-resistance connection can be formed between the source region 2002, the first sinker region 2004, and optionally the second sinker region 2008, and the source electrode (not shown in FIG. 2F).

### Source Contact Regions With Rounded and/or Angular Geometry

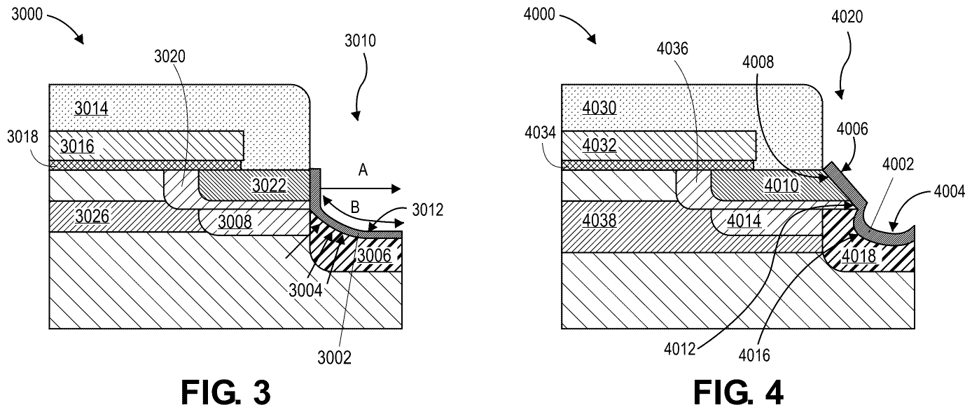

FIG. 3 depicts a simplified partial cross-sectional view of a transistor device 3000 during an intermediate manufacturing step, according to embodiments of the disclosure. As shown in FIG. 3, the transistor device 3000 may be similar in both structure and manufacture to the transistor device 1000 described in conjunction with FIGS. 1A-1E, and/or the transistor device 2000 described in conjunction with FIGS. 2A-2F; however, the transistor device 3000 includes ohmic contacts 3002 with rounded corners 3004, according to an embodiment. The rounded corners 3004 can reduce electrical corner effects (e.g., current crowding), which reduction can improve transistor reliability and can increase the surface area between each ohmic contact 3002 and each first sinker region 3006, thus decreasing a contact resistance between a source metal (not shown in FIG. 3) and the first sinker regions (and optionally between the source metal and second sinker regions 3008). Furthermore, although FIG. 3 depicts only one rounded corner 3004 of the trench 3010 in only two dimensions, it is understood that one or more of the remaining bottom corners of the trench can be rounded, and that such rounding of each rounded corner can be in two or three dimensions. Moreover, although not depicted in FIG. 3, if rounded, the portion of the bottom corner of the trench 3010 to the right of, and in the same plane as, the rounded corner 3004 can be the mirror image of the rounded corner 3004.

In addition, the transistor device 3000 may be, or may include, any of the components, features, or characteristics of any of the transistor devices 1000 or 2000 previously described in conjunction with FIGS. 1A-1E and 2A-2F, respectively. And the features of transistor device 3000 may be included in any of the transistor devices 1000 or 2000 as previously described.

In some embodiments, the rounded corners 3004 may be formed using an anisotropic dry or wet etching process during the formation of trench (e.g., source contact) regions 3010. In an embodiment, a silicon-tetrachloride-(SiCl4)-based inductively coupled plasma reactive ion etch (ICP-RIE) may be used to form the rounded corners 3004. In some embodiments, the anisotropic etching process may be used only at the end of the etching of the trenches 3010. Furthermore, in an embodiment, a width A of a rounded corner 3004 is less than a length of a path B along a curve 3012 along the rounded corner. Moreover, the transistor device 3000 also can include an ILD 3014, conductive (e.g., polysilicon) gates 3016, gate insulators (e.g., oxides or other dielectrics) 3018, well regions (e.g., doped P⁺) 3020, source regions (e.g., doped N⁺) 3022, the second sinker regions 3008 (e.g., doped P⁺), and CSL 3026, which may be similar to the corresponding regions of the transistors 1000 and 2000 described above in conjunction with FIGS. 1A-1E and 2A-2F, respectively. In addition, although FIG. 3 depicts manufacture and intermediate structures of only a portion of the transistor device 3000, it is understood that the remaining portions of the transistor device can be formed and structured in a similar manner.

FIG. 4 depicts a simplified partial cross-sectional view of a transistor device 4000 during an intermediate manufacturing step, according to embodiments of the disclosure. As shown in FIG. 4 and described herein, the transistor device 4000 may be similar to the transistor device 1000 described in conjunction with FIGS. 1A-1E, the transistor device 2000 described in conjunction with FIGS. 2A-2F, or the transistor device 3000 described in conjunction with FIG. 3, but unlike the transistors 1000, 2000, and 3000, the transistor device 4000 includes an ohmic contact 4002 with a rounded corner 4004 and/or an angular sidewall 4006 contiguous with an area 4008 of a source region (e.g., doped N⁺) 4010 and with an area 4012 of a well (e.g., doped P⁺) region 4035, and optionally with an area 4016 of a first sinker (e.g., doped P⁺) region 4018 and/or with an area (not shown in FIG. 4) of a second sinker (e.g., doped P⁺) region 4014. The rounded corner 4004, the angular sidewall 4006, or the combination of the rounded corner and the angular sidewall can reduce electric-field and charge corner effects (e.g., current crowding), which reduction can improve reliability of the transistor 4000, and, compared to a non-angled-sidewall or non-rounded-corner ohmic contact, can increase the area 4008 of contact between the ohmic contact 4002 and the source region 4010, the area 4012 of contact between the ohmic contact 4002 and the well region 4036, the area of contact between the ohmic contact 4002 and the second sinker region 4014, or the area 4016 of contact between the ohmic contact 4002 and the first sinker region 4018, and, therefore, can reduce the respective contact resistances between the ohmic contact 4002 and the source region, the well region, the second sinker region, or the first sinker region. Furthermore, although FIG. 4 depicts only one ohmic contract 4002 having the rounded corner 4004 and the angled sidewall 4006 of the trench 4020 in two dimensions, it is understood that one or more of the remaining bottom corners of the trench can be rounded, and/or one or more of the remaining trench sidewalls can be angled, and that such rounding or angling of each rounded corner and angled trench sidewall can be in two or three dimensions. Moreover, although not depicted in FIG. 4, if rounded and angled, the portions of the bottom corner and sidewall of the trench 4020 to the right of, and in the same plane as, the rounded corner 4002 and angular sidewall 4006 can be the mirror image of the rounded corner 4002 and angular sidewall 4006. In addition, although FIG. 4 describes manufacture and intermediate structures of only a portion of the transistor device 2000, it is understood that the remaining portions of the transistor device can be formed or structured in a similar manner.

In some embodiments, the rounded corner 4004 and angular sidewall 4006 may be formed using an anisotropic dry or wet etching process during the formation of the trenches (e.g., source contact regions) 4020—each trench includes contacts between the ohmic contact 4002 and the source region 4010, the ohmic contact and the well region 4036, the ohmic contact and the second sinker region 4014 (not shown in FIG. 4), or the ohmic contact 4002 and the first sinker region 4018. In an embodiment, a silicon-tetrachloride-(SiCl4)-based inductively coupled plasma reactive ion etch (ICP-RIE) may be used to form the rounded and slanted geometries of the ohmic contact 4002. In some embodiments, the anisotropic etching process may be used only at the end of the etching of the trenches (e.g., source contact regions) 4020. In further embodiments an isotropic etch-back process may be used after the recess (e.g., trench) formation to form the angular interface.

Furthermore, the transistor device 4000 also can include an ILD 4030, conductive (e.g., polysilicon) gate 4032, gate insulator (e.g., oxide or other dielectric) 4034, the well region (e.g., P⁺) 4036, or the CSL 4038, which may be similar to the corresponding regions of the transistors 1000, 2000, and 3000 described above in conjunction with FIGS. 1A-1E, FIGS. 2A-2F, and FIG. 3, respectively.

The transistor device 4000 may be, or may include, any of the components, features, or characteristics of any of the transistor devices 1000, 2000, or 3000 previously described. Furthermore, the features of the transistor device 4000 may be included in any of the transistor devices 1000, 2000, or 3000 as previously described.

Referring to FIGS. 1A-4, although the transistor devices 1000, 2000, 3000, and 4000 are described as being formed in an N-type substrate with an N-type active layer and having N-type source regions and P-type well regions, first sinker regions, and second sinker regions, also contemplated are duals of theses transistor devices in which the substrate, active layer, and source regions are P-type and the well, first sinker, and second sinker regions are N-type. Furthermore, in the transistor devices 1000, 2000, 3000, and 4000, the respective second sinker regions 1018, 2008, 3008, and 4014 may be electrically coupled to the source conductors in the respective trenches 1022, 2006, 3010, and 4000 via the respective well regions 1016, 2010, 3020, and 4036 and/or the respective first sinker regions 1020, 2004, 3006, and 4018, or may extend to the respective trenches between the respective well regions and the respective first sinker regions.

Terms such as “top”, “bottom”, “up”, or “down” are used herein for illustrative purposes only and do not indicate an absolute orientation of any component or part thereof. For example, a substrate of a device is herein sometimes referred to as having a bottom surface, regardless of an overall orientation of a transistor device. Similarly, a side of the device that is on an opposite side of such a bottom surface, and therefore faces away from the bottom surface of the substrate, is sometimes herein referred to as a top surface, again only indicating an orientation relative to the substrate of the transistor device. The terms up and down are used in a similar sense herein.

The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions and equivalents falling within the spirit and scope of the disclosure, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. The phrase “based on” should be understood to be open-ended, and not limiting in any way, and is intended to be interpreted or otherwise read as “based at least in part on,” where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is otherwise understood within the context as used in general to present that an item, term, etc., may be either X, Y, or Z, or any subcombination or combination thereof (e.g., X, Y, and/or Z). Thus, such disjunctive language is not generally intended to, and should not, imply that certain embodiments require at least one of X, at least one of Y, and at least one of Z to each be present. Additionally, conjunctive language such as the phrase “at least one of X, Y, and Z,” unless specifically stated otherwise, should also be understood to mean X, Y, Z, or any subcombination or combination thereof, including “X, Y, and/or Z.”

Preferred embodiments of this disclosure are described herein, including the best mode known to the inventors for carrying out the disclosure. Variations of those preferred embodiments may become apparent to those of ordinary skill in the art upon reading the foregoing description. The inventors expect skilled artisans to employ such variations as appropriate, and the inventors intend for the disclosure to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

All references, including publications, patent applications, and patents, cited herein are hereby incorporated by reference to the same extent as if each reference were individually and specifically indicated to be incorporated by reference and were set forth in its entirety herein.

1. A transistor device, comprising:
a semiconductor substrate having an active region of a first conductivity type; at least one stripe region disposed in the active region and each including:
a well region of a second conductivity type having a first depth;
a source region of a second conductivity type disposed within the well region and having a second depth that is less than the first depth;
trenches spaced apart and extending through the source region and into the well region, each trench having at least one sidewall; and
a source conductor disposed in each of the trenches and electrically coupled to the source region via at least one of the at least one side wall and to the well region.

2. The transistor device of claim 1, wherein:
the first conductivity type is N-type; and
the second conductivity type is P-type.

3. The transistor device of claim 1, further comprising an ohmic contact disposed between the source conductor and one or more of the at least one sidewall of each trench.

4. The transistor device of claim 1, further comprising:
a first ohmic contact disposed between one or more of the at least one sidewall of each trench and the source conductor; and
a second ohmic contact disposed between another one or more of the at least one sidewall of each trench and the source conductor.

5. The transistor device of claim 4, wherein the first ohmic contact has a different composition than the second ohmic contact.

6. The transistor device of claim 1, wherein the trenches are spaced apart from one another by a spacing distance.

7. The transistor device of claim 1, wherein each trench has at least one rounded corner.

8. The transistor device of claim 1, wherein:
the well region has a first length and a first width; and
the source region has a second length that is shorter than the first length and has a second width that is narrower than the first width.

9. The transistor device of claim 1, wherein one or more of the at least one sidewall of each of the trenches are sloped toward an inside of the trench such that a width of the trench and a length of the trench are greater at a top surface of each trench than at a bottom surface of the trench.

10. The transistor device of claim 1, wherein each of the trenches includes at least one rounded corner at a bottom of the trench.

11. The transistor device of claim 1, wherein each stripe region further includes a first sinker region disposed in the active region beneath the trench and having the second conductivity type.

12. The transistor device of claim 11, wherein each stripe region further includes a second sinker region disposed in the active region adjacent to the well region and the first sinker region and having the second conductivity type.

13. The transistor device of claim 1, further comprising multiple stripe regions having a pitch.

14. The transistor device of claim 1, wherein each of the stripe regions further comprises:
a gate insulator disposed over a portion of the well region adjacent to a top surface of the substrate;
a conductive gate disposed over the gate insulator; and
an interlayer dielectric disposed between the gate and the source conductor.

15. The transistor device of claim 1, wherein each of the stripe regions further comprises a charge-spreading layer disposed in the active region adjacent to the well region.

16. The transistor device of claim 1, wherein each of the stripe regions further comprises a charge-spreading layer disposed in the active region adjacent to the second sinker region.

17. The transistor device of claim 11, wherein the source contact is electrically coupled to the well region via the first sinker region.

18. The transistor device of claim 12, wherein the source contact is electrically coupled to the well region via the second sinker region.

19. The transistor of claim 1, wherein the semiconductor substrate comprises an SiC semiconductor substrate.

20. A method of forming a transistor device, the method comprising, in each of at least one stripe region of an active region of a substrate, the active region having a first conductivity type:
forming a well region having a second conductivity type, a first length, a first width, and a first depth;
forming, in the well region, a source region having the first conductivity type, a second length, a second width, and a second depth less than the first depth;
forming a first sinker region having the second conductivity type, a third length, a third width, and a third depth equal to or greater than the first depth such that the first sinker region extends through the second sinker region or the well region;
forming, over the semiconductor substrate, a mask having at least one aperture over the source region;
forming, in the active region through the at least one aperture, at least one trench having a fourth length and a fourth width defined by the at least one aperture, the at least one trench having a fourth depth greater than the second depth such that the at least one trench extends through the source region; and
forming, in the at least one trench, an electrically conductive material that is electrically coupled with the source region, the well region, and the first sinker region.

21. The method of claim 20, wherein forming the at least one trench comprises forming multiple trenches that are spaced apart from one another.

22. The method of claim 20, wherein forming the at least one trench comprises forming the at least one trench having at least one rounded bottom corner.

23. The method of claim 20, wherein forming the at least one trench comprises forming the at least one trench having at least one sloped side wall.

24. The method of claim 20, further comprising forming, in the active region, a second sinker region having the second conductivity type and having a fourth depth that is greater than the first depth and less than the third depth.
